(19) United States
(12) Patent Application Publication
(10) Pub. No.: US 2012/0306543 A1
(43) Pub. Date: Dec. 6, 2012

(54) SEMICONDUCTOR DEVICE INCLUDING OUTPUT DRIVER

(75) Inventor: Fumiyoshi MATSUOKA, Kawasaki-shi (JP)

(73) Assignee: KABUSHIKI KAISHA TOSHIBA, Tokyo (JP)

(21) Appl. No.: 13/423,587

(22) Filed: Mar. 19, 2012

(30) Foreign Application Priority Data
May 31, 2011 (JP) 2011-122418

(51) Int. Cl. H03K 3/00

(52) U.S. Cl. 327/108

(57) ABSTRACT

According to one embodiment, a semiconductor device includes first and second pull-up deriver units, a pull-down driver unit, and a calibration circuit including a comparator. The first and second pull-up driver units adjust a pull-up driver. The pull-down driver unit adjusts a pull-down driver. When calibrating the pull-up driver, the calibration circuit causes the comparator to compare a reference voltage with the output voltage of the first pull-up driver unit based on a reference resistance. When calibrating the pull-down driver, the calibration circuit causes the comparator to compare the reference voltage with the voltage of a connection node between the second pull-up driver unit and pull-down driver unit.

### CROSS-REFERENCE TO RELATED APPLICATIONS

This application is based upon and claims the benefit of priority from prior Japanese Patent Application No. 2011-122418, filed May 31, 2011, the entire contents of which are incorporated herein by reference.

### FIELD

Embodiments described herein relate generally to a semiconductor device capable of calibrating the drivability of an output driver.

### BACKGROUND

A memory such as a DRAM achieves a high-speed operation by adopting a double data rate (DDR) by which data is input and output at the leading edge and trailing edge of a clock signal in order to increase the access efficiency.

A double-data-rate output driver includes a pull-up driver unit that pulls up output data, and a pull-down driver unit that pulls down output data. The drivability of the pull-up driver unit and that of the pull-down driver unit are preferably equal to a desirable value. Therefore, a calibration circuit for calibrating the drivabilities of the pull-up driver unit and pull-down driver unit has been developed. However, the variations of elements forming the calibration circuit deteriorate the calibration accuracy. Accordingly, demands have arisen for a semiconductor device capable of increasing the accuracy of calibration of the drivability of the output driver.

### BRIEF DESCRIPTION OF THE DRAWINGS

FIG. 1 is a circuit diagram showing an example of a calibration circuit of a general pull-up driver unit;

FIG. 2 is a circuit diagram showing an example of a calibration circuit of a general pull-down driver unit;

FIG. 3 is a circuit diagram showing a semiconductor device according to the first embodiment;

FIG. 4 is a circuit diagram showing an example of an output driver of the semiconductor device according to the first embodiment; and

FIG. 5 is a circuit diagram showing a semiconductor device according to the second embodiment.

### DETAILED DESCRIPTION

In general, according to one embodiment, a semiconductor device includes first and second pull-up deriver units, a pull-down driver unit, and a calibration circuit including a comparator. The first and second pull-up driver units adjust a pull-up driver whose output signal drivability is adjustable. The pull-down driver unit adjusts a pull-down driver whose output signal drivability is adjustable. When calibrating the pull-up driver, the calibration circuit causes the comparator to compare a reference voltage with the output voltage of the first pull-up driver unit based on a reference resistance and output a first comparison result, and determines the drivabilities of the first and second pull-up driver units based on the first comparison result. When calibrating the pull-down driver, the calibration circuit causes the comparator to compare the reference voltage with the voltage of a connection node between the second pull-up driver unit and pull-down driver unit and output a second comparison result, and determines the drivability of the pull-down driver unit based on the second comparison result.

An embodiment will be explained below with reference to the accompanying drawings.

This embodiment has a feature that when performing a calibration operation in a device having a function of calibrating the drivability of an output driver, the drivabilities of a pull-up driver unit and pull-down driver unit are adjusted by using a single comparator, thereby suppressing the variation in slew rate of an output waveform, which is caused by the difference of the drivability from a reference resistance, and reducing deterioration of the output waveform quality. This makes it possible to provide an output driver capable of holding a stable slew rate and achieving high output waveform quality, against variations in process, power supply voltage, and temperature.

As described above, the differences of the drivabilities of a pull-up driver unit and pull-down driver unit of an output driver from a reference value reduce an effective time during which data can be latched on the data receiving side. This poses a serious problem in a high-speed operation.

Recently, therefore, the output driver has a calibration function, and a calibration circuit can calibrate the drivabilities of a pull-up driver unit and pull-down driver unit.

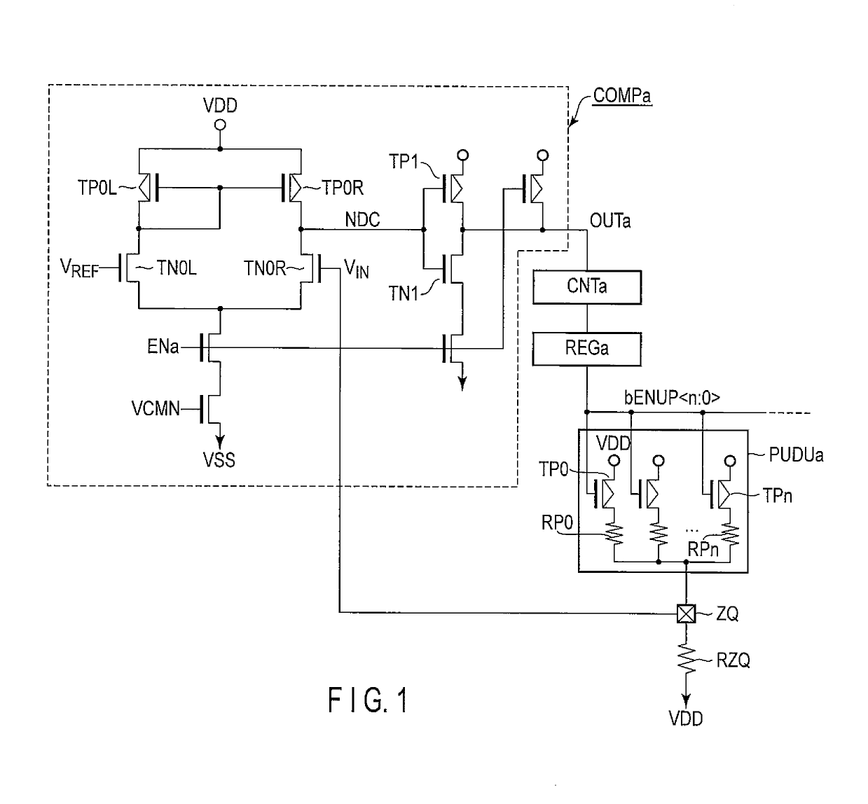

FIG. 1 shows the arrangement of a calibration circuit of a general pull-up driver unit PUDUa. The calibration circuit of the pull-up driver unit PUDUa includes a comparator COMPa, counter CNTa, register REGa, and calibration pad ZQ, and a reference resistance RZQ is connected between the pad ZQ and a ground potential (VSS). The reference resistance RZQ is connected outside a semiconductor chip.

A reference voltage V_{REF} is applied to the gate electrode of an N-channel MOS transistor (to be referred to as an NMOS transistor hereinafter) TN0L forming the inverting input terminal of the comparator COMPa. The gate electrode of an NMOS transistor TN0R forming the noninverting input terminal is connected to the pad ZQ. The counter CNTa is connected to an output node OUTa of the comparator COMPa, and the register REGa is connected to the output terminal of the counter CNTa.

The output terminal of the register REGa outputs calibration bit signals bENUP<n:0> (b indicates “low active”) having, e.g., (n+1) (n is a natural number) bits. The plurality of signals bENUP<n:0> are respectively supplied to the gate electrodes of a plurality of P-channel MOS transistors (to be referred to as PMOS transistors hereinafter) TP0 to TPn forming the pull-up driver unit PUDUa. The PMOS transistors TP0 to TPn have, e.g., sequentially increased gate widths, and hence have different current drivabilities. Each PMOS transistor has a source connected to a power supply VDD, and a drain connected to one terminal of a corresponding one of a plurality of resistors RP0 to RPn having different values. The other terminal of each of the resistors RP0 to RPn is connected to the pad ZQ.

In the above-mentioned arrangement, calibration is executed by the following sequence. First, the comparator COMPa compares the reference voltage V_{REF} with the voltage of the pad ZQ. Then, the plurality of PMOS transistors TP0 to TPn in the pull-up driver unit PUDUa are sequentially activated, such that an electric current flowing through the reference resistance RZQ is almost equal to an electric current flowing through the pull-up driver unit PUDUa.

That is, the counter CNTa is counted up in accordance with the output signal OUTa from the comparator COMPa, and the output signal from the counter CNTa is supplied to the pull-up driver unit PUDUa via the register REGa. The output signals bENUP<n:0> from the register REGa activate the PMOS transistors in ascending order from the PMOS transistor TP0 having the smallest size.

After the above operation is repeated, if the comparator COMPa determines that the voltage of the pad ZQ and the reference voltage V_{REF} (VDD/2) are equal, the calibration bit signal bENUP<n:0> is determined. That is, if it is detected that electric currents flowing through the reference resistance RZQ and a selected PMOS transistor are equal, the count-up of the counter CNTa is stopped, and the calibration bit signal bENUP<n:0> for selecting a PMOS transistor is determined. The determined signal bENUP<n:0> is held in the register REGa, and supplied to a pull-up driver unit PUDUb having the same arrangement as that of the pull-up driver unit PUDUa. The pull-up driver unit PUDUb will be described below.

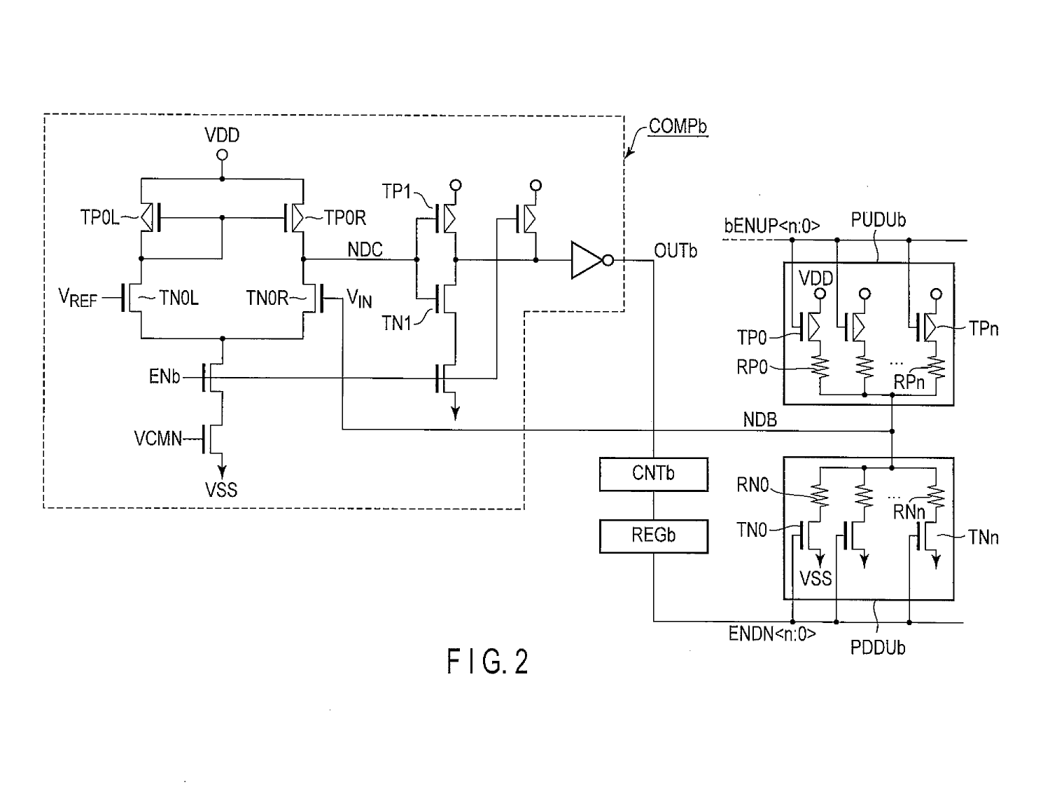

FIG. 2 shows the arrangement of a calibration circuit of a general pull-down driver unit PDDUb. The calibration circuit of the pull-down driver unit PDDUb includes the pull-up driver unit PUDUb, the pull-down driver unit PDDUb, a comparator COMPb, a counter CNTb, and a register REGb.

The pull-up driver unit PUDUb and pull-down driver unit PDDUb are connected by a node NDB. The arrangement of the pull-up driver unit PUDUb is the same as that of the pull-up driver unit PUDUa. The pull-down driver unit PDDUb includes, e.g., (n+1) resistors RN0 to RNn and (n+1) NMOS transistors TN0 to TNn. Each of the resistors RN0 to RNn has one terminal connected to the node NDB, and the other terminal connected to the drain of a corresponding one of the NMOS transistors TN0 to TNn. The sources of the NMOS transistors TN0 to TNn are grounded. The NMOS transistors TN0 to TNn have, e.g., sequentially increased gate widths.

The comparator COMPb compares the reference voltage V_{REF} with the voltage of the node NDB. An output node OUTb of the comparator COMPb is connected to the counter CNTb, and the output terminal of the counter CNTb is connected to the register REGb. Calibration bit signals ENDN<n:0> output from the register REGb are respectively supplied to the gate electrodes of the NMOS transistors TN0 to TNn of the pull-down driver unit PDDUb.

In the pull-up driver unit PUDUb in the above-mentioned arrangement, as described previously, one or a plurality of PMOS transistors are selected and activated from the plurality of PMOS transistors TP0 to TPn in accordance with the calibration bit signals bENUP<n:0> supplied from the calibration circuit of the pull-up driver unit PUDUa.

The comparator COMPb performs control such that an electric current flowing through the pull-up driver unit PUDUb is almost equal to an electric current flowing through the pull-down driver unit PDDUb. That is, the comparator COMPb compares the reference voltage V_{REF} with the voltage of the node NDB, and the counter CNTb is counted up by the output signal from the comparator COMPb. The output signal from the counter CNTb is supplied to the register REGb, and the calibration bit signals ENDN<n:0> output from the register REGb sequentially activate the NMOS transistors TN0 to TNn in the pull-down driver unit PDDUb in ascending order of size.

When the voltage of the node NDB becomes equal to the reference voltage V_{REF} (VDD/2), the comparator COMPb stops the count-up operation of the counter CNTb. That is, the comparator COMPb stops the count-up by the counter CNTb when detecting that the electric current flowing through the PMOS transistor of the pull-up driver unit PUDUb is equal to the electric current flowing through the NMOS transistor of the pull-down driver unit PDDUb. Consequently, the calibration bit signal ENDN<n:0> for selecting an NMOS transistor to be activated is determined, and the determined signal is held in the register REGb. The calibration bit signal ENDN<n:0> is a so-called, high-active signal for turning on a High-level NMOS transistor.

As will be described later, an output driver connected to each output pad (not shown) includes a plurality of pull-up driver units PUDU0, PUDU1, . . . , PUDUm having the same arrangement as that of the pull-up driver units PUDUa and PUDUb in the calibration circuits, and a plurality of pull-down driver units PDDU0, PDDU1, . . . , PDDUm having the same arrangement as that of the pull-down driver unit PDDUb, and the bit signals bENUP<n:0> and ENDN<n:0> determined by the calibration circuits are supplied to each unit. The calibration results are thus reflected on the output drivers.

The comparator COMPa forming the calibration circuit of the pull-up driver units PUDUa and PUDUb shown in FIG. 1 becomes operable when an enable signal EN is High level. The comparator COMPa compares the reference voltage V_{REF} with a voltage V_{IN} (the voltage of the pad ZQ). If the voltage V_{IN} is higher than the reference voltage V_{REF}, the output node OUTa changes to High level.

As described above, in the calibration operation of the pull-up driver unit PUDUa, the counter CNTa sequentially activates the PMOS transistors in ascending order of size. As the count-up of the counter CNTa progresses, therefore, the voltage of a node NDC of the comparator COMPa gradually decreases. When the voltage V_{IN} becomes equal to the reference voltage V_{REF}, the output node OUTa changes to High level, the count-up of the counter CNTa stops, and the calibration bit signal bENUP<n:0> is determined.

Also, the comparator COMPb forming the calibration circuit of the pull-down driver unit PDDUb shown in FIG. 2 is connected to the output node OUTb via one inverter circuit stage, but has the same basic arrangement as that of the comparator COMPa.

The comparator COMPb becomes operable when the enable signal EN is High level. The comparator COMPb compares the reference voltage V_{REF} with the voltage V_{IN} (the voltage of the node NDB). When the voltage V_{IN} becomes lower than the reference voltage V_{REF}, the output node OUTb changes to High level.

As described above, in the calibration operation of the pull-down driver unit PDDUb, the counter CNTb sequentially activates the NMOS transistors in ascending order of size. As the count-up of the counter CNTb progresses, therefore, the voltage of the node NDC of the comparator COMPb gradually increases. When the voltage V_{IN} becomes equal to the reference voltage V_{REF}, the output node OUTb changes to High level, the count-up of the counter CNTb stops, and the calibration bit signal ENDN<n:0> is determined.

The comparators COMPa and COMPb are differential comparators. The voltage of the node NDC varies with respect to the level of the voltage V_{IN}, owing to the unbalance of the electrical characteristics of the NMOS transistors TN0L and TN0R forming a differential pair, and the unbalance of the electrical characteristics of PMOS transistors TP0L and TP0R forming a current-mirror circuit.

In addition, since the electrical characteristics of the PMOS transistor TP1 and NMOS transistor TN1 also vary, the threshold voltage of an inverter circuit including these transistors and having the node NDC as an input terminal varies. Consequently, the accuracy of calibration of the pull-up driver units PUDUa and PUDUb and pull-down driver unit PDDUb deteriorate owing to the variations in characteristics of the elements forming the comparators COMPa and COMPb.

Assume that in the comparator COMPa, the electrical characteristics of the NMOS transistors TN0L and TN0R are unbalanced, e.g., the threshold voltage of the NMOS transistor TN0R is lower than that of the NMOS transistor TN0L.

First, the calibration operation of the pull-up driver unit PUDUa is performed. The result is compared with an ideal case, i.e., a case in which the threshold voltages of the NMOS transistors TN0L and TN0R are completely equal. In this case, the drivability of a PMOS transistor to be activated decreases so that an electric current flowing through the NMOS transistor TN0R having the gate electrode to which the voltage of the pad ZQ is applied is almost equal to an electric current flowing through the NMOS transistor TN0L having the gate electrode to which the reference voltage V_{REF} is applied. That is, the drivability of the pull-up driver is set smaller than an ideal value.

Subsequently, the calibration operation of the pull-down driver unit PDDUb is performed. The calibration bit signal bENUP<n:0> determined by the previously performed calibration operation of the pull-up driver unit PUDUa is already supplied to the pull-up driver unit PUDUb connected to the pull-down driver unit PDDUb.

Assume the worst situation, i.e., assume that in the comparator COMPb, the threshold voltage of the NMOS transistor TN0R is higher than that of the NMOS transistor TN0L, in contrast with the comparator COMPa. Accordingly, the drivability of an NMOS transistor to be activated when the electric current flowing through the NMOS transistor TN0R having the gate electrode to which the voltage of the node NDB is applied becomes almost equal to the electric current flowing through the NMOS transistor TN0L having the gate electrode to which the reference voltage V_{REF} is applied is further lower than the previously determined drivability of the PMOS transistor to be activated in the pull-up driver unit. Since this increases the difference of the drivability of the pull-down driver unit from the reference resistance RZQ, the drivability is set further lower than that of the pull-up driver.

As described above, when the drivabilities of a pull-up driver unit and pull-down driver unit are calibrated by calibration circuits by using two comparators, the variations of elements forming the two comparators deteriorate the accuracy of calibration of the drivabilities of pull-up and pull-down with respect to the reference resistance RZQ. This reduces the effective time of output data, and may deteriorate the quality of a waveform.

### First Embodiment

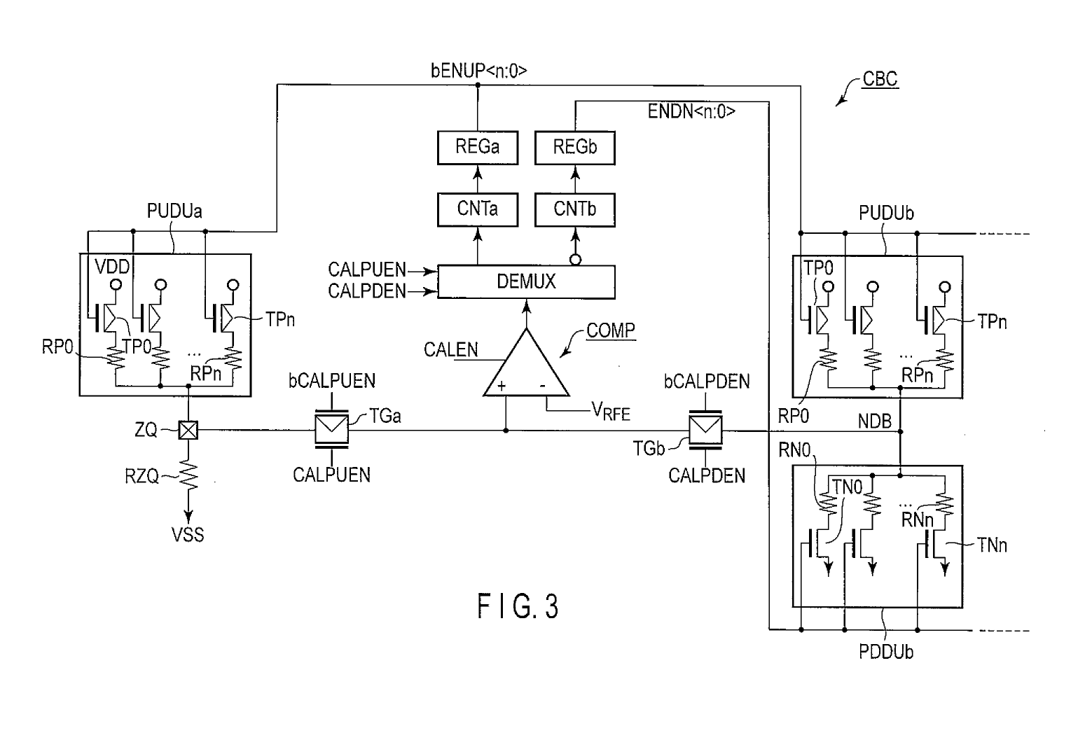

FIG. 3 shows the arrangement of a calibration circuit CBC of a semiconductor device according to the first embodiment. In the first embodiment, the drivabilities of a pull-up driver unit and pull-down driver unit can be calibrated by using a single comparator COMP. In FIG. 3, the same reference numerals as in FIGS. 1 and 2 denote the same parts.

Referring to FIG. 3, the arrangement of the comparator COMP is, e.g., the same as that of the comparator COMPa shown in FIG. 1. The noninverting input terminal of the comparator COMP is connected, via a transfer gate TGa, to a pad ZQ which forms a calibration circuit of a pull-up driver unit PUDUa, and to which a resistance RZQ is connected. The noninverting input terminal of the comparator COMP is also connected to a node NDB forming a calibration circuit of a pull-down driver unit PDDUb, via a transfer gate TGb.

An enable signal CALPUEN for enabling calibration of the pull-up driver unit PUDUa is supplied to the gate electrode of an NMOS transistor forming the transfer gate TGa, and an inverted signal bCALPUEN of the enable signal CALPUEN is supplied to the gate electrode of a PMOS transistor.

Also, an enable signal CALPDEN for enabling calibration of the pull-down driver unit PDDUa is supplied to the gate electrode of an NMOS transistor forming the transfer gate TGb, and an inverted signal bCALPDEN of the enable signal CALPDEN is supplied to the gate electrode of a PMOS transistor.

A reference voltage V_{REF} is applied to the inverting input terminal of the comparator COMP. The reference voltage V_{REF} is, e.g., a voltage of VDD/2.

The output terminal of the comparator COMP is connected to the input terminal of a demultiplexer DEMUX. The demultiplexer DEMUX has one input terminal and two output terminals, and the two output terminals are switched by the enable signals CALPUEN and CALPDEN as control signals. A counter CNTa forming the calibration circuit of the pull-up driver unit PUDUa is connected to the first output terminal. A counter CNTb forming the calibration circuit of the pull-down driver unit PDDUb is connected to the second output terminal.

When the enable signal CALPUEN is High level, the demultiplexer DEMUX outputs the signal from the comparator COMP to the counter CNTa. When the enable signal CALPDEN is High level, the demultiplexer DEMUX inverts the signal from the comparator COMP and outputs the inverted signal to the counter CNTb.

The output signals from the counters CNTa and CNTb are respectively supplied to registers REGa and REGb. Calibration bit signals bENUP<n:0> output from the register REGa are supplied to the gate electrodes of a plurality of PMOS transistors TP0 to TPn forming the pull-up driver unit PUDUa. Also, calibration bit signals ENDN<n:0> output from the register REGb are supplied to the gate electrodes of a plurality of NMOS transistors TN0 to TNn forming the pull-down driver unit PDDUb.

In the above arrangement, the calibration operation of the first embodiment is executed by the following sequence.

First, the calibration operation of the pull-up driver unit PUDUa is executed. In this case, the enable signal CALPUEN is set at High level, and the enable signal CALPDEN is set at Low level. Accordingly, the transfer gate TGa is turned on, and the transfer gate TGb is turned off. As a consequence, the noninverting input terminal of the comparator COMP is electrically connected to the pad ZQ via the transfer gate TGa. Also, the demultiplexer DEMUX selects the first output terminal to which the comparator COMP is connected, in accordance with the enable signal CALPUEN.

In this state, the comparator COMP performs control such that an electric current flowing through the reference resistance RZQ is almost equal to an electric current flowing through the pull-up driver unit PUDUa. That is, the comparator COMP compares the voltage of the node ZQ with the reference voltage V_{REF}, and outputs a Low-level signal if the voltage of the node ZQ is lower than the reference voltage V_{REF}. This signal is supplied to the counter CNTa via the first output terminal of the demultiplexer DEMUX.

The counter CNTa is counted up in accordance with the output signal from the demultiplexer DEMUX. The output signal from the counter CNTa is supplied to the register REGa, and the register REGa outputs the calibration bit signals bENUP<n:0>.

In the pull-up driver unit PUDUa, the plurality of PMOS transistors TP0 to TPn are activated in ascending order from a PMOS transistor having the smallest size, i.e., the smallest gate width, in accordance with the calibration bit signals bENUP<n:0>.

After the above operation is repeated, if the voltage of the pad ZQ becomes equal to the reference voltage V_{REF} (VDD/2), i.e., if the electric current flowing through the reference resistance RZQ becomes equal to the electric current flowing through a selected PMOS transistor, the comparator COMP stops the count-up by the counter CNTa. Consequently, the calibration bit signal bENUP<n:0> for selecting a PMOS transistor to be activated is determined. The determined signal bENUP<n:0> is held in the register REGa, and supplied to the pull-up driver unit PUDUb having the same arrangement as that of the pull-up driver unit PUDUa.

Then, the calibration operation of the pull-down driver unit PDDUb is executed. In this case, the enable signal CALPUEN is set at Low level, and the enable signal CALPDEN is set at High level. Therefore, the transfer gate TGb is turned on, and the transfer gate TGa is turned off. As a result, the noninverting input terminal of the comparator COMP is electrically connected to the node NDB via the transfer gate TGb. Also, the demultiplexer DEMUX selects the second output terminal to which the counter CNTb is connected, in accordance with the activated enable signal CALPDEN.

In this state, the comparator COMP performs control such that an electric current flowing through the pull-up driver unit PUDUb is almost equal to an electric current flowing through the pull-down driver unit PDDUb. That is, the comparator COMP compares the voltage of the node NDB with the reference voltage V_{REF}, and outputs a Low-level signal if the voltage of the node NDB is lower than the reference voltage V_{REF}. This signal is supplied to the counter CNTb via the second output terminal of the demultiplexer DEMUX.

The counter CNTb is counted up in accordance with the output signal from the demultiplexer DEMUX. The output signal from the counter CNTb is supplied to the register REGb, and the register REGb outputs the calibration bit signals ENDN<n:0>.

In the pull-down driver unit PDDUb, the plurality of NMOS transistors TN0 to TNn are activated in ascending order from an NMOS transistor having the smallest size, i.e., the smallest gate width, in accordance with the calibration bit signals ENDN<n:0>.

After the above operation is repeated, if the voltage of the node NDB becomes equal to the reference voltage V_{REF} (VDD/2), i.e., if the electric current flowing through a selected PMOS transistor in the pull-up driver unit PUDUb becomes equal to the electric current flowing through a selected NMOS transistor in the pull-down driver unit PDDUb, the comparator COMP stops the count-up by the counter CNTb. Consequently, the calibration bit signal ENDN<n:0> for selecting an NMOS transistor to be activated is determined. The determined signal ENDN<n:0> is held in the register REGb.

As described above, the calibration circuit using the single comparator COMP completes the calibration of the pull-up driver units PUDUa and PUDUb and pull-down driver unit PDDUb.

In comparison with the comparator COMPa shown in FIG. 1, assume that in the comparator COMP of the first embodiment, the electrical characteristics of NMOS transistors TN0L and TN0R are unbalanced, e.g., the threshold voltage of the NMOS transistor TN0R is lower than that of the NMOS transistor TN0L. First, the calibration operation of the pull-up driver unit PUDUa is performed as described above. Compared to an ideal case, i.e., a case in which the threshold voltages of the NMOS transistors TN0L and TN0R are completely equal, the drivability of a PMOS transistor to be activated decreases such that an electric current flowing through the NMOS transistor TN0R having a gate electrode to which the voltage of the pad ZQ is applied is almost equal to an electric current flowing through the NMOS transistor TN0L having a gate electrode to which the reference voltage V_{REF} is applied. That is, the drivability of the pull-up driver unit PUDUa is set smaller than an ideal value.

Subsequently, the calibration operation of the pull-down driver unit PDDUb is performed as described above. The calibration bit signals bENUP<n:0> determined by the calibration operation of the pull-up driver unit PUDUa are already supplied to the pull-up driver unit PUDUb connected to the pull-down driver unit PDDUb.

Unlike the arrangements shown in FIGS. 1 and 2, the calibration circuit of the first embodiment calibrates the pull-up driver unit and pull-down driver unit by using the same comparator COMP. In the calibration of the pull-down driver unit, therefore, the relationship between the threshold voltages of the NMOS transistors TN0R and TN0L is the same as that in the calibration of the pull-up driver unit, i.e., the threshold voltage of the NMOS transistor TN0R is lower than that of the NMOS transistor TN0L.

Accordingly, the drivability of the NMOS transistor to be activated when the electric current flowing through the NMOS transistor TN0R having the gate electrode to which the voltage of the node NDB is applied is almost equal to the electric current flowing through the NMOS transistor TN0L having the gate electrode to which the reference voltage V_{REF} is applied becomes higher than the previously determined drivability of the PMOS transistor to be activated by the pull-up driver unit, and approaches the reference resistance RZQ. Therefore, the difference of the drivability of the pull-down driver unit from the reference resistance RZQ does not exceed the difference of the pull-up driver unit, and is set close to the resistance value. This makes it possible to decrease the difference of the drivability of the pull-down driver unit from the reference resistance, which is due to the variations in electrical characteristics of the transistors of the calibration circuit.

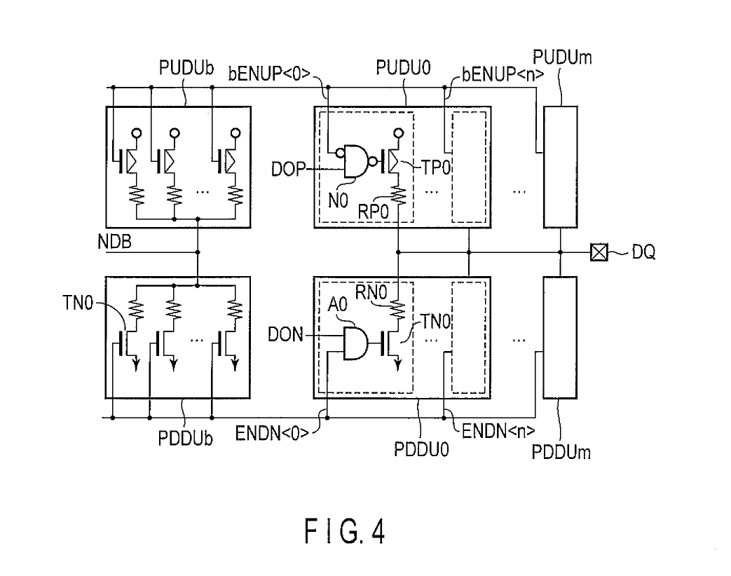

FIG. 4 shows the relationship between the pull-up driver unit PUDUb and pull-down driver unit PDDUb forming the above-mentioned calibration circuit, and output drivers connected to an output terminal DQ of the semiconductor device, i.e., a pull-up driver unit PUDU0 and pull-down driver unit PDDU0.

Similar to the pull-up driver unit PUDUa, the pull-up driver unit PUDU0 includes a plurality of PMOS transistors TP0 to TPn, a plurality of resistors RP0 to RPn, and NAND logic circuits N0 to Nn. Similar to the pull-down driver unit PDDUb, the pull-down driver unit PDDU0 includes a plurality of NMOS transistors TN0 to TNn, a plurality of resistors RN0 to RNn, and AND logic circuits A0 to An. FIG. 4 shows only the PMOS transistor TP0, resistor RP0, NAND logic circuit N0, NMOS transistor TN0, resistor RN0, and AND logic circuit A0.

In the pull-up driver unit PUDU0, the PMOS transistors TP0 to TPn have sources to which a power supply voltage VDD is applied, and drains connected to the node NDB via the resistors RP0 to RPn. Each of the calibration bit signals bENUP<n:0> output from the register REGa is inverted and supplied to one input terminal of a corresponding one of the NAND logic circuits N0 to Nn. A signal D0P supplied from an internal circuit of the semiconductor device is supplied to the other input terminal of each of the NAND logic circuits N0 to Nn. The output signals from the NAND logic circuits N0 to Nn are respectively supplied to the gate electrodes of the PMOS transistors TP0 to TPn.

In the pull-down driver unit PDDU0, each of the plurality of resistors RN0 to RNn has one terminal connected to the output pad DQ, and the other terminal connected to the drain of a corresponding one of the NMOS transistors TN0 to TNn. The sources of the NMOS transistors TN0 to TNn are grounded. Each of the calibration bit signals ENDN<n:0> output from the register REGb is supplied to one input terminal of a corresponding one of the AND logic circuits A0 to An. A signal DON supplied from an internal circuit of the semiconductor device is supplied to the other input terminal of each of the AND logic circuits A0 to An. The output signals from the AND logic circuits A0 to An are respectively supplied to the gate electrodes of the NMOS transistors TN0 to TNn.

In the above arrangement, the pull-up drivability of the pull-up driver unit PUDU0 and the pull-down drivability of the pull-down driver unit PDDU0 are set almost equal to each other by the calibration bit signals bENUP<n:0> and ENDN<n:0>.

Note that the output drivers shown in FIG. 4 include a plurality of pull-up driver units PUDU0 to PUDUm and pull-down driver units PDDU0 to PDDUm for which different output resistances are set. A pull-up driver unit PUDUi (i is a natural number from 0 to m) and a pull-down driver unit PDDUi have drivabilities obtained by equally multiplying the drivabilities of the pull-up driver unit PUDU0 and pull-down driver unit PDDU0 as references. Accordingly, the output drivers shown in FIG. 4 can select a plurality of drivabilities by using the pair of the pull-up driver unit PUDU0 and pull-down driver unit PDDU0 adjusted to have an ON resistance equal to the reference resistance RZQ, and selectively combining the plurality of driver unit pairs PUDUm and PDDUm having drivabilities obtained by equally multiplying the drivabilities of the pull-up driver unit PUDU0 and pull-down driver unit PDDU0.

In the above-mentioned first embodiment, the pull-up driver unit and pull-down driver unit are calibrated by using the single comparator COMP. Therefore, when compared to a case in which a pull-up driver unit and pull-down driver unit are calibrated by using different comparators, it is possible to decrease the difference of the drivability from the reference resistance RZQ, and increase the calibration accuracy. Accordingly, the variations in slew rate at the leading edge and trailing edge of output data can be suppressed. This makes it possible to provide an output driver capable of holding a stable slew rate and achieving high output waveform quality, against variations in process, power supply voltage, and temperature.

Note that in the calibration operation of the pull-up driver unit (a pull-down sub driver unit) of this embodiment, the drivability is determined by sequentially activating the PMOS transistors (NMOS transistors) in ascending order of size. However, the calibration operation can also be executed by using, e.g., a binary search algorithm. In this case, the drivability is determined by repeating count-up and count-down, and the same effect as that of this embodiment can be obtained.

### Second Embodiment

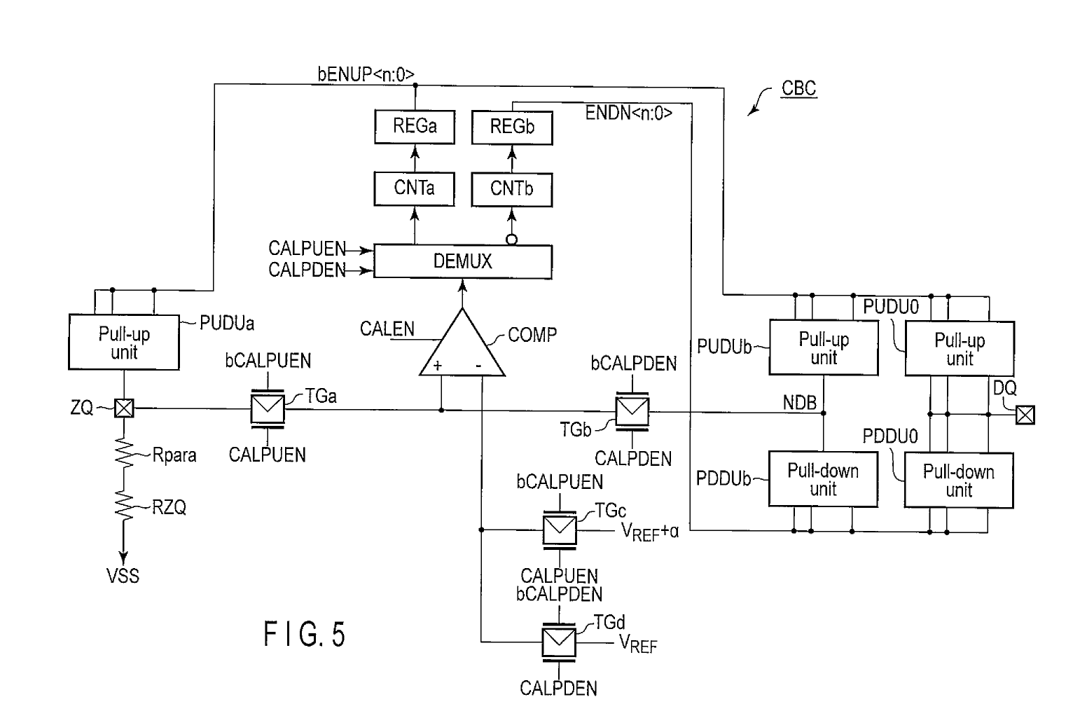

FIG. 5 shows the second embodiment. The same reference numerals as in the first embodiment denote the same parts in FIG. 5, and only different portions will be explained.

In FIG. 5, a reference resistance RZQ is connected to a pad ZQ. That is, the reference resistance RZQ is formed outside a semiconductor device, and has a parasitic resistance component Rpara. The parasitic resistance component Rpara is connected in series with the reference resistance RZQ. When the calibration operation of a pull-up driver unit PUDUa is performed with the reference resistance RZQ including the parasitic resistance component Rpara, an electric current flowing through the reference resistance RZQ reduces, so the output resistance of the pull-up driver unit is set higher than the reference resistance RZQ.

Accordingly, the second embodiment can further increase the calibration accuracy by removing the influence of the parasitic resistance included in the reference resistance RZQ.

In the second embodiment, therefore, one terminal of each of transfer gates TGc and TGd is connected to the inverting input terminal of a comparator COMP. A voltage of reference voltage V_{REF}+α is applied to the other terminal of the transfer gate TGc, and the reference voltage V_{REF} is applied to the other terminal of the transfer gate TGd. The voltage α is a voltage generated by the parasitic resistance component Rpara.

An enable signal CALPUEN for enabling the calibration of the pull-up driver unit PUDUa is supplied to the gate electrode of an NMOS transistor forming the transfer gate TGc, and an inverted signal bCALPUEN of the enable signal CALPUEN is supplied to the gate electrode of a PMOS transistor.

Also, an enable signal CALPDEN for enabling the calibration of a pull-down driver unit PDDUb is supplied to the gate electrode of an NMOS transistor forming the transfer gate TGd, and an inverted signal bCALPDEN of the enable signal CALPDEN is supplied to the gate electrode of a PMOS transistor.

When executing the calibration operation of the pull-up driver unit PUDUa in the above arrangement, the enable signals CALPUEN and bCALPUEN are activated, and the enable signals CALPDEN and bCALPDEN are inactivated. Therefore, the transfer gate TGc is turned on, and the transfer gate TGd is turned off. Consequently, the voltage of reference voltage V_{REF}+α is applied to the inverting input terminal of the comparator COMP via the transfer gate TGc.

The comparator COMP compares the reference voltage V_{REF}+α with the voltage of the pad ZQ. By setting the voltage α as an offset for the reference voltage V_{REF}, it is possible to correct the reduction in electric current flowing through the reference resistance RZQ by the parasitic resistance component Rpara, and eliminate the difference of the set output resistance of the pull-up driver unit from the reference resistance RZQ. Accordingly, the pull-up driver can be calibrated by removing the reduction in electric current flowing through the reference resistance RZQ based on the parasitic resistance component Rpara.

Next, when executing the calibration operation of the pull-down driver unit PDDUb, the enable signals CALPDEN and bCALPDEN are activated, and the enable signals CALPUEN and bCALPUEN are inactivated. Therefore, the transfer gate TGd is turned on, and the transfer gate TGc is turned off. Consequently, the reference voltage V_{REF} is applied to the inverting input terminal of the comparator COMP via the transfer gate TGd.

The comparator COMP compares the voltage of the node NDB with the reference voltage V_{REF}, and executes the calibration operation of the pull-down driver unit PDDUb, in the same manner as in the first embodiment.

In the second embodiment described above, the voltage of reference voltage V_{REF}+α or the reference voltage V_{REF} can be applied to the inverting input terminal of the comparator COMP via the transfer gate TGc or TGd. When calibrating the pull-up driver unit PUDUa, the voltage of reference voltage V_{REF}+α is applied to the inverting input terminal of the comparator COMP via the transfer gate TGc. When calibrating the pull-down driver unit PDDUb, the reference voltage V_{REF} is applied to the inverting input terminal of the comparator COMP via the transfer gate TGd. Therefore, the parasitic resistance component Rpara included in the reference resistance RZQ can be canceled. This makes it possible to increase both the accuracy of calibration of the pull-up driver unit PUDUa, and the accuracy of calibration of the pull-down driver unit PDDUb.

Note that this embodiment is not limited to an output driver of a DRAM, and is, of course, applicable to memories other than a DRAM and other semiconductor devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first pull-up driver unit and a second pull-up driver unit configured to adjust a pull-up driver whose output signal drivability is adjustable;
a pull-down driver unit configured to adjust a pull-down driver whose output signal drivability is adjustable; and
a calibration circuit comprising a comparator,
wherein the calibration circuit is configured to calibrate the pull-up driver by causing the comparator to compare a reference voltage with an output voltage of the first pull-up driver unit based on a reference resistance and to output a first comparison result, and the calibration circuit further configured to determine the drivabilities of the first pull-up driver unit and the second pull-up driver unit based on the first comparison result, and the calibration circuit further configured to cause the comparator to compare the reference voltage with a voltage of a connection node between the second pull-up driver unit and the pull-down driver unit and to output a second comparison result, and the calibration circuit further configured to determine the drivability of the pull-down driver unit based on the second comparison result.

2. The device according to claim 1, wherein the calibration circuit comprises:
a first signal generator configured to generate a signal for adjusting the drivabilities of the first pull-up driver unit and the second pull-up driver unit;
a second signal generator configured to generate a signal for adjusting the drivability of the pull-down driver unit;
a first transfer gate configured to supply the output voltage of the first pull-up driver unit based on the reference resistance to the comparator, when calibrating the pull-up driver;
a second transfer gate configured to apply a voltage of the connection node to the comparator, when calibrating the pull-down driver; and
a demultiplexer configured to supply an output signal of the comparator to the first signal generator when calibrating the pull-up driver, and supply the output signal of the comparator to the second signal generator when calibrating the pull-down driver.

3. The device according to claim 2, further comprising a third transfer gate having one terminal connected to the comparator, and the other terminal configured to receive a voltage higher than the reference voltage by an amount which corrects a reduction in electric current caused by a parasitic resistance component of the reference resistance,
wherein the third transfer gate is turned on when calibrating the pull-down driver.

4. The device according to claim 2, further comprising a fourth transfer gate having one terminal connected to the comparator, and the other terminal configured to receive the reference voltage,
wherein the fourth transfer gate is configured to be turned on when calibrating the pull-down driver.

5. The device according to claim 2, wherein the first signal generator comprises:
a first counter which is configured to be counted up based on a signal supplied from the demultiplexer; and
a first register configured to hold an output signal of the first counter.

6. The device according to claim 2, wherein the second signal generator comprises:
a second counter which is configured to be counted up based on a signal supplied from the demultiplexer; and
a second register configured to hold an output signal of the second counter.

7. A semiconductor device comprising:
a first pull-up driver unit and a second pull-up driver unit configured to adjust a pull-up driver whose output signal drivability is adjustable;
a pull-down driver unit configured to adjust a pull-down driver whose output signal drivability is adjustable;
a calibration circuit comprising a comparator;
a first transfer gate configured to connect the first pull-up driver unit to the comparator when calibrating the pull-up driver; and
a second transfer gate configured to connect the second pull-up driver unit and the pull-down driver unit to the comparator when calibrating the pull-down driver,
wherein the calibration circuit is configured to calibrate the pull-up driver by causing the comparator to compare a reference voltage with an output voltage of the first pull-up driver unit based on a reference resistance and to output a first comparison result, and the calibration circuit further configured to determine the drivabilities of the first pull-up driver unit and the second pull-up driver unit based on the first comparison result, and the calibration circuit further configured to cause the comparator to compare the reference voltage with a voltage of a connection node between the second pull-up driver unit and the pull-down driver unit and to output a second comparison result, and the calibration circuit further configured to determine the drivability of the pull-down driver unit based on the second comparison result.

8. The device according to claim 7, wherein the calibration circuit comprises:
a first signal generator configured to generate a signal for adjusting the drivabilities of the first pull-up driver unit and the second pull-up driver unit;
a second signal generator configured to generate a signal for adjusting the drivability of the pull-down driver unit; and
a demultiplexer configured to supply an output signal of the comparator to the first signal generator when calibrating the pull-up driver, and supply the output signal of the comparator to the second signal generator when calibrating the pull-down driver.

9. The device according to claim 8, further comprising a third transfer gate having one terminal connected to the comparator, and the other terminal configured to receive a voltage higher than the reference voltage by an amount which corrects a reduction in electric current caused by a parasitic resistance component of the reference resistance,
wherein the third transfer gate is turned on when calibrating the pull-down driver.

10. The device according to claim 8, further comprising a fourth transfer gate having one terminal connected to the comparator, and the other terminal configured to receive the reference voltage,
wherein the fourth transfer gate is configured to be turned on when calibrating the pull-down driver.

11. The device according to claim 8, wherein the first signal generator comprises:
a first counter which is configured to be counted up based on a signal supplied from the demultiplexer; and
a first register configured to hold an output signal of the first counter.

12. The device according to claim 8, wherein the second signal generator comprises:
a second counter which is configured to be counted up based on a signal supplied from the demultiplexer; and
a second register configured to hold an output signal of the second counter.
